(19) United States
(12) Patent Application Publication
(10) Pub. No.: US 2007/0205420 A1
(43) Pub. Date: Sep. 6, 2007

(54) ELECTROLUMINESCENT DISPLAY DEVICES

(75) Inventors: Marc W.G. Ponjee, Eindhoven (NL); Wouter Oepts, Eindhoven (NL); Johannes J.W.M. Rosink, Geldrop (NL); Hans-Helmut Bechtel, Roetgen (NL); Nigel D. Young, Redhill (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/599,082

(22) PCT Filed: Mar. 22, 2005
(86) PCT No.: PCT/IB05/50982

§ 371 Date: Sep. 19, 2006

(30) Foreign Application Priority Data
Mar. 24, 2004 (GB) 0406540.5
Nov. 19, 2004 (GB) 0425505.5

(51) Int. Cl. H01L 27/15

(52) U.S. Cl. 257/80; 257/E27.12

(57) ABSTRACT

An active matrix display device comprises an array of display pixels provided over a common substrate (60). Each pixel has an upwardly emitting current-driven light emitting display element (2) comprising a lower electrode (74) and an upper substantially transparent electrode (80a. A light sensitive device (27) for sensing the display element (2) light output is positioned between the substrate (60) and the display element (2), and a drive transistor (22) is controlled in response to the light-sensitive device (27) output. The lower electrode (74) of the display element is partially transmissive to transmit at most 20% of the light incident on the lower electrode, at least a portion of the transmitted light being directed to the underlying light-sensitive device (27).

This invention relates to electroluminescent display devices, particularly active matrix display devices having an array of pixels comprising light-emitting electroluminescent display elements and thin film transistors. More particularly, but not exclusively, the invention is concerned with an active matrix electroluminescent display device whose pixels include light sensing elements which are responsive to light emitted by the display elements and used in the control of energisation of the display elements.

Matrix display devices employing electroluminescent, light-emitting, display elements are well known. The display elements commonly comprise organic thin film electroluminescent elements, (OLEDs), including polymer materials (PLEDs), or else light emitting diodes (LEDs). The term LED used below is intended to cover all of these possibilities. These materials typically comprise one or more layers of a semiconducting conjugated polymer sandwiched between a pair of electrodes, one of which is transparent and the other of which is of a material suitable for injecting holes or electrons into the polymer layer.

The display elements in such display devices are current driven and a conventional, analogue, drive scheme involves supplying a controllable current to the display element. Typically a current source transistor is provided as part of the pixel configuration, with the gate voltage supplied to the current source transistor determining the current through the electroluminescent (EL) display element. A storage capacitor holds the gate voltage after the addressing phase. An example of such a pixel circuit is described in EP-A-0717446.

Each pixel thus comprises the EL display element and associated driver circuitry. The driver circuitry has an address transistor which is turned on by a row address pulse on a row conductor. When the address transistor is turned on, a data voltage on a column conductor can pass to the remainder of the pixel. In particular, the address transistor supplies the column conductor voltage to the current source, comprising the drive transistor and the storage capacitor connected to the gate of the drive transistor. The column, data, voltage is provided to the gate of the drive transistor and the gate is held at this voltage by the storage capacitor even after the row address pulse has ended. The drive transistor in this circuit is implemented as a p-channel TFT, (Thin Film Transistor) so that the storage capacitor holds the gate-source voltage fixed. This results in a fixed source-drain current through the transistor, which therefore provides the desired current source operation of the pixel. The brightness of the EL display element is approximately proportional to the current flowing through it.

In the above basic pixel circuit, differential ageing, or degradation, of the LED material, leading to a reduction in the brightness level of a pixel for a given drive current, can give rise to variations in image quality across a display. A display element that has been used extensively will be much dimmer than a display element that has been used rarely. Also, display non-uniformity problems can arise due to the variability in the characteristics of the drive transistors, particularly the threshold voltage level.

Improved voltage-addressed pixel circuits which can compensate for the ageing of the LED material and variation in transistor characteristics have been proposed. These include a light sensing element which is responsive to the light output of the display element and acts to leak stored charge on the storage capacitor in response to the light output so as to control the integrated light output of the display element during the drive period which follows the initial addressing of the pixel. Examples of this type of pixel configuration are described in detail in WO 01/20591 and EP 1 096 466. In an example embodiment, a photodiode in the pixel discharges the gate voltage stored on the storage capacitor and the EL display element ceases to emit when the gate voltage on the drive transistor reaches the threshold voltage, at which time the storage capacitor stops discharging. The rate at which charge is leaked from the photodiode is a function of the display element output, so that the photodiode serves as a light-sensitive feedback device.

The optical feedback arrangement enables compensation for initial non-uniformity between TFTs and display elements, as well as changes in these non-uniformities over time. The light output from a display element is independent of the EL display element efficiency and ageing compensation is thereby provided. Such a technique has been shown to be effective in achieving a high quality display which suffers less from non-uniformities over a period of time. However, this method requires a high instantaneous peak brightness level to achieve adequate average brightness from a pixel in a frame time and this is not beneficial to the operation of the display as the LED material is likely to age more rapidly as a result.

In an alternative approach, the optical feedback system is used to change the duty cycle with which the display element is operated. The display element is driven to a fixed brightness, and the optical feedback is used to trigger a transistor switch which turns off the drive transistor rapidly. This avoids the need for high instantaneous brightness levels, but introduces additional complexity to the pixel.

The use of optical feedback systems is considered as an effective way of overcoming differential ageing of the LED display elements.

A path of light must be provided between the LED display element and the photo-sensitive device. One problem which arises is that any stray light which is not absorbed by the photo-sensitive device can be captured by the photosensitive device of a different pixel. Furthermore, the path of ambient light to the photo-sensitive device should be avoided.

In a bottom (downwardly) emitting structure, the light output passes from the EL layer, through the underlying thin film layers defining the active matrix pixel circuitry, and through the substrate beneath. The photo-sensitive device can then be formed from the thin film layers, and one side of the photosensitive device faces the EL layer for light capture, while the opposite side faces the display output surface. This makes it possible for the photo-sensitive device to provide shielding from ambient light.

In a top (upwardly) emitting structure, the light output passes from the EL layer out of the display through an overlying transparent cathode electrode. With the photo-sensitive device formed from the thin film layers beneath the EL layer, the same side of the photosensitive device faces the EL layer and ambient light, so that shielding of the ambient light becomes an issue. Furthermore, the anode beneath the EL layer should ideally be opaque to provide display contrast, and the passage of light to the photo-sensitive device becomes an issue.

This invention relates to these top emitting structures.

According to the invention, there is provided an active matrix display device comprising an array of display pixels provided over a common substrate, each pixel comprising:

a drive transistor circuit provided over the substrate; and

an upwardly emitting current-driven light emitting display element provided over the drive transistor circuit, and comprising a lower electrode and an upper substantially transparent electrode; and

a light sensitive device for sensing the display element light output and positioned between the substrate and the display element,

wherein a drive transistor of the drive transistor circuit is controlled in response to the light-sensitive device output, and

wherein the lower electrode of the display element is partially transmissive to transmit at most 20% of the light incident on the lower electrode, at least a portion of the transmitted light being directed to the underlying light-sensitive device.

In this description and claims, the term “upwardly emitting” means that the display output to the user is in a direction from the light sensitive device away from (not through) the substrate. The display element itself may emit light in all direction, but the display output to the user is upwardly from the substrate.

The lower electrode, which may be the anode, is partially transmissive so that some of the display output can reach the light sensitive device. Because the light sensitive device is beneath the display element, its size does not affect the pixel aperture, so it can be made large enough to be sensitive to the small proportion of the display output which is allowed to reach the light sensitive device.

The lower electrode may for example comprise a metal layer having a transmission of 1% to 10%, and may comprise a metal film of 10 nm to 60 nm A conductive transparent layer may overly the metal film layer to improve the electrical characteristics.

In an alternative arrangement, the lower electrode comprises a substantially opaque layer provided with an opening in the vicinity of the light sensitive device. This allows almost all of the electrode to be fully reflective (or absorbing) which improves the display contrast ratio.

A substantially transparent conductive material can be provided in the opening in order to maintain electrical driving of the display element. This transparent conductive material may form a layer overlying the opaque layer, so that the drive characteristics are more uniform across the display element.

The light sensitive device can be positioned beneath and laterally to one side of the opening, and this reduces the incidence of ambient light on the light sensitive device.

The light sensitive device can be a phototransistor or a photodiode.

The device may further comprise light blocking elements provided on top of the upper electrode and overlying the light sensitive devices of the pixels. These can reduce the ambient light reaching the light sensitive device. The light blocking elements may be formed from a metal layer which also defines resistance reducing shunt portions for the upper electrode.

Examples of the invention will now be described in detail with reference to the accompanying drawings, in which:

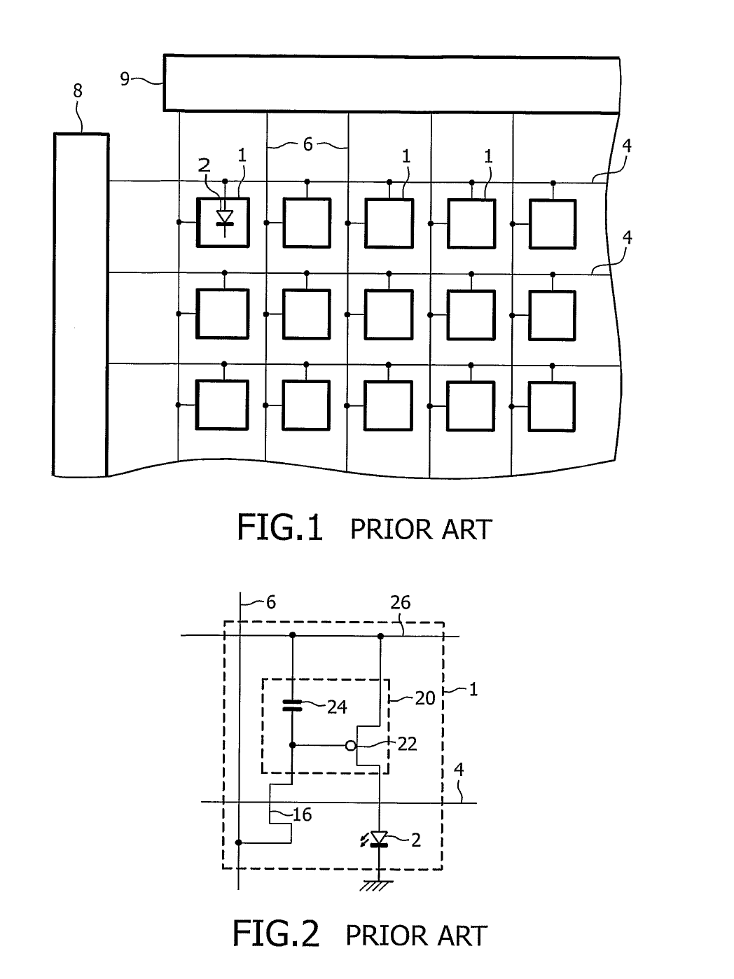

FIG. 1 is a simplified schematic diagram of an embodiment of active matrix EL display device;

FIG. 2 illustrates a known form of pixel circuit;

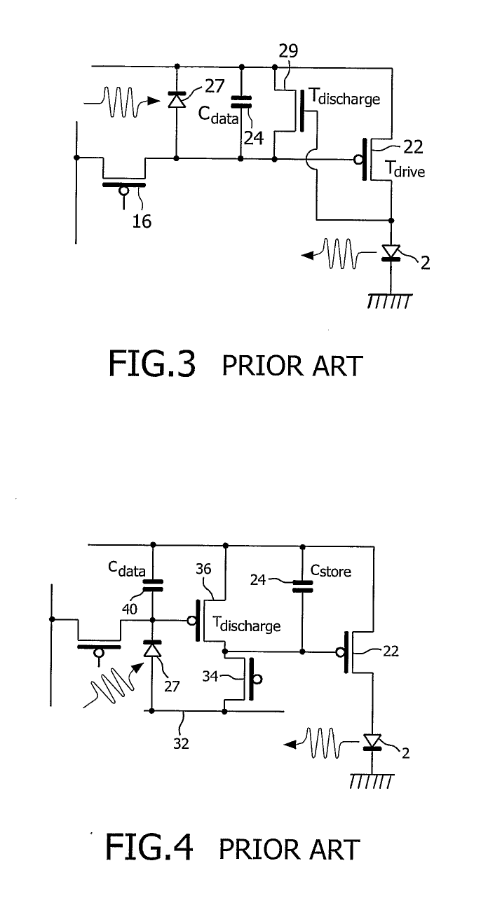

FIG. 3 shows a first known optical feedback pixel design;

FIG. 4 shows a second known optical feedback pixel design;

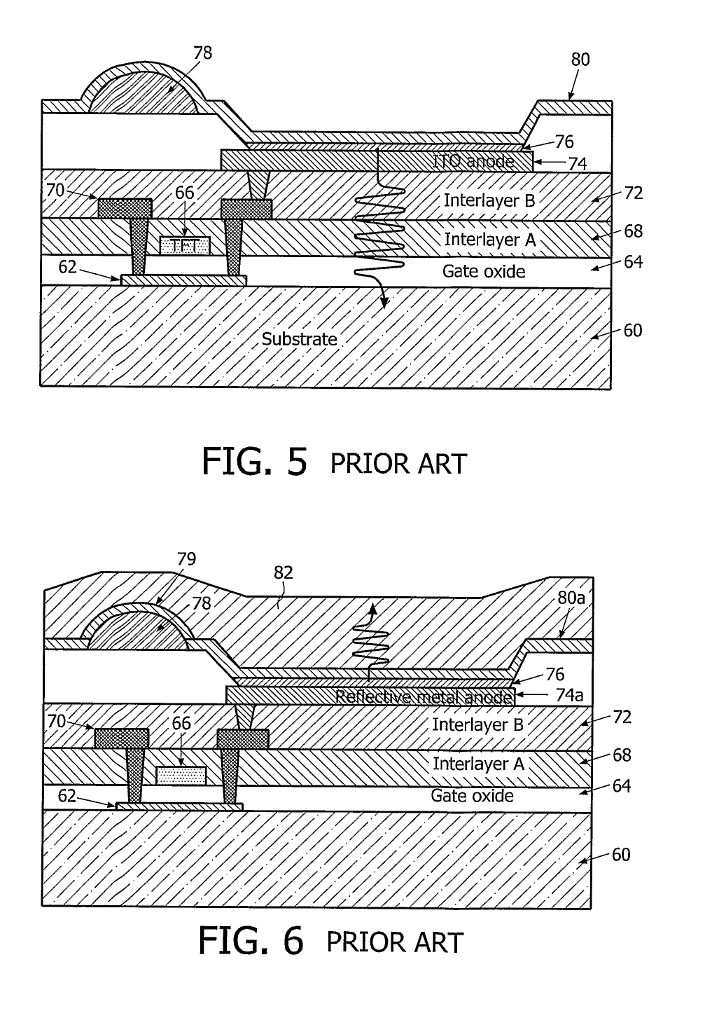

FIG. 5 shows a known structure of a bottom emitting display pixel;

FIG. 6 shows a known structure of a top emitting display pixel;

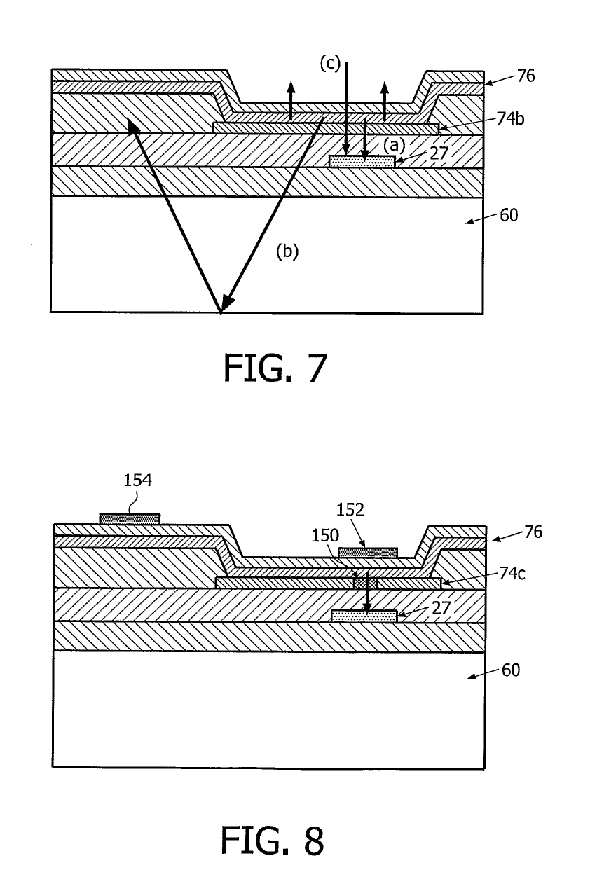

FIG. 7 shows a first way of providing a light path to the light-sensitive element in a top emitting display in accordance with the invention;

FIG. 8 shows a second way of providing a light path to the light-sensitive element in a top emitting display in accordance with the invention;

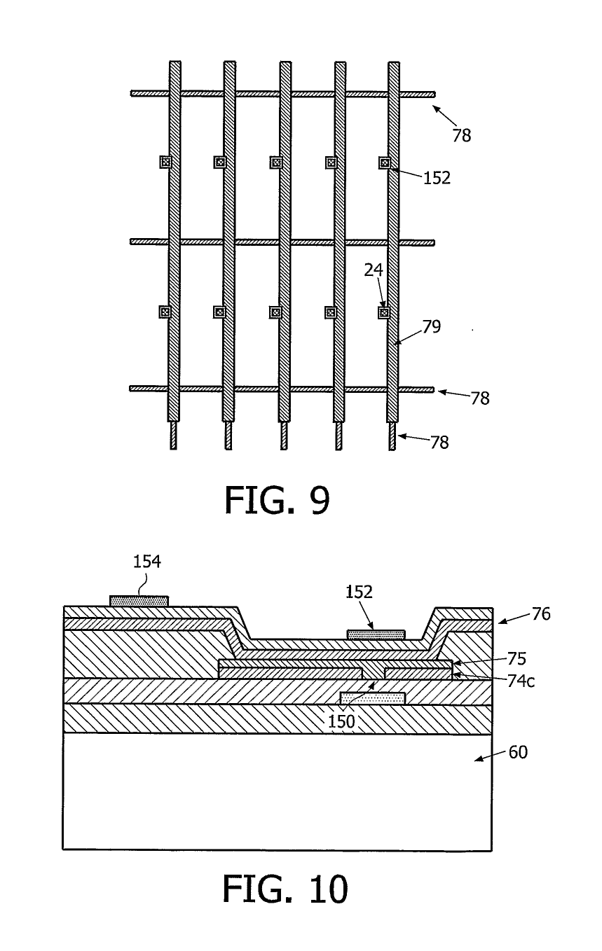

FIG. 9 shows the light blocking elements used in the device of FIG. 8 more clearly;

FIG. 10 shows a first modification to the device of FIG. 8;

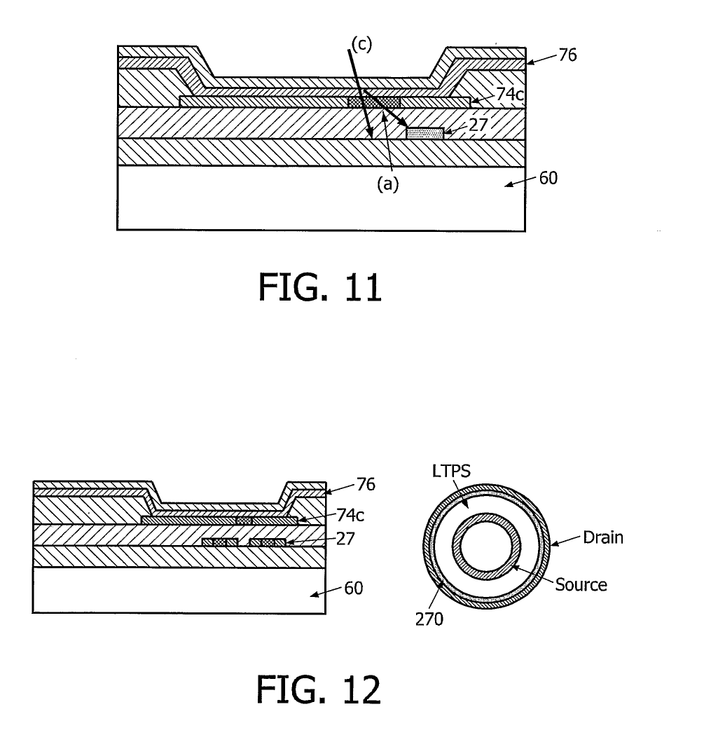

FIG. 11 shows a second modification to the device of FIG. 8;

FIG. 12 shows a third modification to the device of FIG. 8;

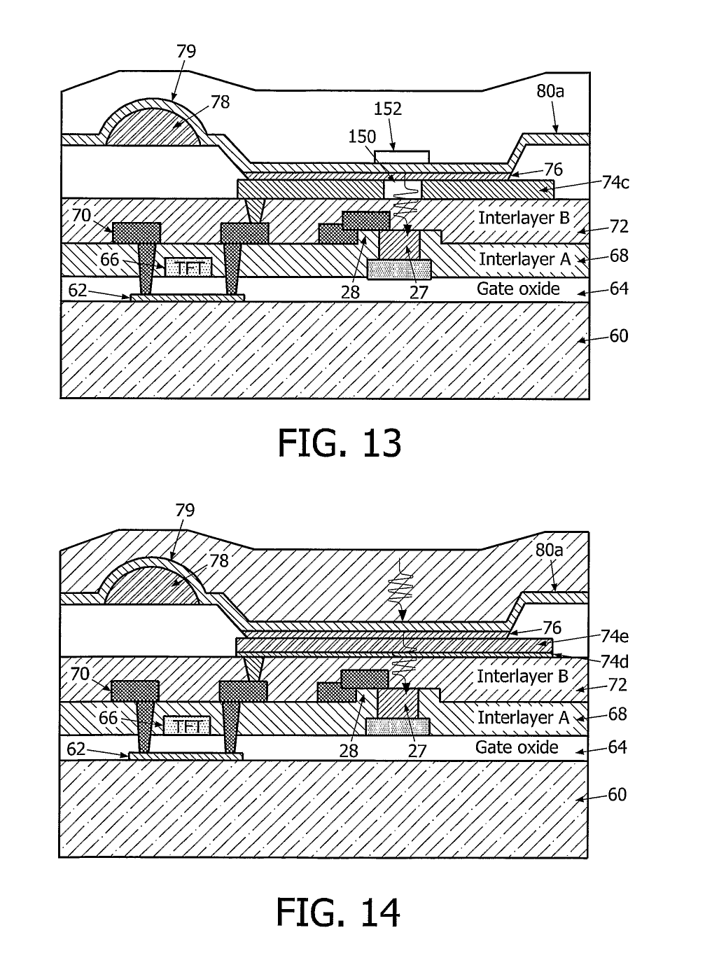

FIG. 13 shows in more detail one possible construction of the device of FIG. 10; and

FIG. 14 shows in more detail one possible construction of the device of FIG. 7.

The same reference numbers are used throughout the Figures to denote the same or similar parts.

FIG. 1 shows a known active matrix electroluminescent display device. The display device comprises a panel having a row and column matrix array of regularly-spaced pixels, denoted by the blocks 1 and comprising electroluminescent display elements 2 together with associated switching means, located at the intersections between crossing sets of row (selection) and column (data) address conductors 4 and 6. Only a few pixels are shown in the Figure for simplicity. In practice there may be several hundred rows and columns of pixels. The pixels 1 are addressed via the sets of row and column address conductors by a peripheral drive circuit comprising a row, scanning, driver circuit 8 and a column, data, driver circuit 9 connected to the ends of the respective sets of conductors.

The electroluminescent display element 2 comprises an organic light emitting diode, represented here as a diode element (LED) and comprising a pair of electrodes between which one or more active layers of organic electroluminescent material is sandwiched. The display elements of the array are carried together with the associated active matrix circuitry on one side of an insulating support. Either the cathodes or the anodes of the display elements are formed of transparent conductive material. The support is of transparent material such as glass and the electrodes of the display elements 2 closest to the substrate may consist of a transparent conductive material such as ITO so that light generated by the electroluminescent layer is transmitted through these electrodes and the support so as to be visible to a viewer at the other side of the support.

FIG. 2 shows in simplified schematic form the most basic pixel and drive circuitry arrangement for providing voltage-addressed operation. Each pixel 1 comprises the EL display element 2 and associated driver circuitry. The driver circuitry has an address transistor 16 which is turned on by a row address pulse on the row conductor 4. When the address transistor 16 is turned on, a voltage on the column conductor 6 can pass to the remainder of the pixel. In particular, the address transistor 16 supplies the column conductor voltage to a current source 20, which comprises a drive transistor 22 and a storage capacitor 24. The column voltage is provided to the gate of the drive transistor 22, and the gate is held at this voltage by the storage capacitor 24 even after the row address pulse has ended.

The drive transistor 22 in this circuit is implemented as a p-type TFT, so that the storage capacitor 24 holds the gate-source voltage fixed. This results in a fixed source-drain current through the transistor, which therefore provides the desired current source operation of the pixel.

In the above basic pixel circuit, for circuits based on polysilicon, there are variations in the threshold voltage of the transistors due to the statistical distribution of the polysilicon grains in the channel of the transistors. Polysilicon transistors are, however, fairly stable under current and voltage stress, so that the threshold voltages remain substantially constant.

The variation in threshold voltage is small in amorphous silicon transistors, at least over short ranges over the substrate, but the threshold voltage is very sensitive to voltage stress. Application of the high voltages above threshold needed for the drive transistor causes large changes in threshold voltage, which changes are dependent on the information content of the displayed image. There will therefore be a large difference in the threshold voltage of an amorphous silicon transistor that is always on compared with one that is not. This differential ageing is a serious problem in LED displays driven with amorphous silicon transistors.

In addition to variations in transistor characteristics there is also differential ageing in the LED itself. This is due to a reduction in the efficiency of the light emitting material after current stressing. In most cases, the more current and charge passed through an LED, the lower the efficiency.

FIGS. 3 and 4 show examples of pixel layout with optical feedback to provide ageing compensation.

In the pixel circuit of FIG. 3, a photodiode 27 discharges the gate voltage stored on the capacitor 24 (C_{data}), causing the brightness to reduce. The display element 2 will no longer emit when the gate voltage on the drive transistor 22 (T_{drive}) reaches the threshold voltage, and the storage capacitor 24 will then stop discharging. The rate at which charge is leaked from the photodiode 27 is a function of the display element output, so that the photodiode 27 functions as a light-sensitive feedback device. Once the drive transistor 22 has switched off, the display element anode voltage reduces causing the discharge transistor 29 (T_{discharge}) to turn on, so that the remaining charge on the storage capacitor 24 is rapidly lost and the luminance is switched off.

As the capacitor holding the gate-source voltage is discharged, the drive current for the display element drops gradually. Thus, the brightness tails off. This gives rise to a lower average light intensity.

FIG. 4 shows a circuit which has been proposed by the applicant, and which has a constant light output and then switches off at a time dependent on the light output.

The gate-source voltage for the drive transistor 22 is again held on a storage capacitor 24 (Cₛₜₒᵣₑ). However, in this circuit, this capacitor 24 is charged to a fixed voltage from a charging line 32, by means of a charging transistor 34. Thus, the drive transistor 22 is driven to a constant level which is independent of the data input to the pixel when the display element is to be illuminated. The brightness is controlled by varying the duty cycle, in particular by varying the time when the drive transistor is turned off.

The drive transistor 22 is turned off by means of a discharge transistor 36 which discharges the storage capacitor 24. When the discharge transistor 36 is turned on, the capacitor 24 is rapidly discharged and the drive transistor turned off.

The discharge transistor 36 is turned on when the gate voltage reaches a sufficient voltage. A photodiode 27 is illuminated by the display element 2 and again generates a photocurrent in dependence on the light output of the display element 2. This photocurrent charges a discharge capacitor 40 (C_{data}), and at a certain point in time, the voltage across the capacitor 40 will reach the threshold voltage of the discharge transistor 36 and thereby switch it on. This time will depend on the charge originally stored on the capacitor 40 and on the photocurrent, which in turn depends on the light output of the display element. The discharge capacitor initially stores a data voltage, so that both the initial data and the optical feedback influence the duty cycle of the circuit.

There are many alternative implementations of pixel circuit with optical feedback. FIGS. 3 and 4 show p-type implementations, and there are also n-type implementations, for example for amorphous silicon transistors.

For completeness, FIG. 5 shows the known basic bottom emission structure including the active matrix.

The device comprises a substrate 60 over which the drive transistor semiconductor body 62 is deposited. A gate oxide dielectric layer 64 covers the semiconductor body, and a top gate electrode 66 is provided over the gate dielectric layer 64.

A first insulating layer 68 (typically silicon dioxide or silicon nitride) provides spacing between the gate electrode (which typically also forms row conductors) and the source and drain electrodes. These source and drain electrodes are defined by a metal layer 70 over the insulator layer 68, and the electrodes connect to the semiconductor body through vias as shown.

A second insulating layer 72 (again typically silicon dioxide or silicon nitride) provides spacing between the source and drain electrodes (which typically also form column conductors) and the LED anode. The LED anode 74 is provided over the second insulating layer 72.

In the case of a bottom emission display as shown in FIG. 5, this bottom anode needs to be at least partially transparent, and ITO is typically used.

The EL material 76 is formed in a well over the anode, and is preferably deposited by printing. Separate sub-pixels are formed for the three primary colours, and a print dam 78 assists in the accurate printing of the different EL materials.

The print dam 78 enables printing of separate pixels. This dam layer is generally made of an insulating polymer and has a height of several microns. A common cathode 80 is provided over the display, and this is reflective and at a common potential for all pixels (ground in FIG. 2).

FIG. 6 shows the basic known top emission structure including the active matrix. The structure is essentially the same as in FIG. 5, but the anode 74a is reflective and the cathode 80a is transmissive. The cathode may again be formed from ITO, but may have a thin metal or silicide coating between the ITO and polymer to control the barrier for electron injection. For example, this may be a thin layer of Barium. Protection and encapsulation layers 82 cover the display.

In a top-emission display, a transparent cathode is needed. The cathode does, however, have to be highly conductive, and at present highly conductive transparent metals are not readily available. Therefore the cathode of top-emission displays comprises a (semi-) transparent layer on top of the emissive pixel part and shunted with a lower resistance conducting (non-transparent) metal 79. By placing this highly conductive metal 79 on top of the dam 78 as shown, there is no loss in pixel aperture.

The anode metal must be a high work function metal, and it is known to provide a layer of ITO on top of a reflective metal to achieve a high work function into the LED stack.

This invention relates specifically to top emitting structures. These have a number of advantages over bottom emitting structures, explained below.

The pixel circuit can be located underneath the light-emitting area of the light emitting element. As a result, the light-emitting area (aperture ratio) can be increased to over 90% of the total display area in top-emitting devices, whereas the fill factor is often below 50% in bottom-emitting devices.

The constraints on the TFT circuit are less severe. In bottom-emitting devices, the TFT circuit has to be as small as possible to make the aperture ratio as large as possible. In top-emitting devices, the TFT circuit can become much larger, which facilitates the use of the amorphous-silicon technology instead of polysilicon technology. The ability to use amorphous silicon technology reduces the cost of active matrix EL significantly since large area manufacturing processes are already available from the LCD industry.

The constraints on the storage capacitor used for opto-electronic feedback are also less severe. In bottom-emitting devices, the storage capacitor again has to be as small as possible to make the aperture ratio as large as possible. As a result, the photocurrents generated by the photosensitive devices in bottom-emitting displays must be very small, for example below 1 nA to appropriately control the TFT gate potentials over a frame period. In top-emitting devices, larger storage capacitors can be applied, which enables the application of higher photocurrents. This allows the use of light sensing elements with higher photosensitivity and/or the use of larger photosensitive areas. For example, a larger photosensitive area is beneficial to monitor the light output more accurately. The top emitting design allows a non-transparent substrate and/or non-transparent bottom-electrode to be used.

The ability to use a non-transparent substrate allows a wider range of substrate materials to be used for the display device, such as flexible steel foils, and puts less or no constraints on the optical quality of the substrate (transparency, absorption, scratches). In addition, in top-emitting devices, wave-guiding of light in the substrate can be prevented when using a non-transparent or reflective substrate. This reduces the loss of light due to wave-guiding in the substrate and prevents pixel cross-talk due to light that travels between pixels through the substrate.

The ability to use a non-transparent anode, such as a reflective anode or absorptive (black) anode also provides further design options. A reflective anode can be used to employ micro-cavity effects to optimise the light-output, and the device efficiency. In combination with a circular polarizer, a metallic reflective anode provides good daylight contrast of the device. This is a method which is already employed in bottom-emitting OLED devices presently on the market. Although, the use of a black anode is less beneficial in view of light-output optimisation using micro-cavity effects, it may provide a sufficient daylight contrast of the device without the need for a polarizer. A black anode may be similar to known black cathode for bottom emission devices.

The implementation of optical feedback in a top-emitting structure does however, presents additional difficulties.

As the light sensing elements are processed together with the active matrix on the substrate, the non-transparent anode layer is positioned between the light sensing elements and the EL layer, and thus prohibits light emitted by the light-emitting material to reach the light sensing elements. Furthermore, ambient light that enters the device via the (semi)transparent cathode will also enter the optical feedback device, which disturbs the opto-electronic feedback and the regulation of the light-output of the light-emitting elements.

The invention provides a pixel structure for an upwardly emitting current-driven light emitting display in which a lower electrode of the display element is partially transmissive. This electrode transmits a portion of the light incident on the lower electrode to an underlying light-sensitive device for optical feedback. Most of the light incident on the lower electrode is, however, reflected or absorbed so that the display device maintains good contrast.

FIGS. 7 to 12 are used to show display structures of the invention more schematically, and the top layers, which are not relevant to the invention, are removed, as well as the drive transistor structure. Thus, FIGS. 7 to 12 are intended to represent more schematically the structure shown in more detail in FIG. 6.

FIG. 7 shows a first way to provide a path of light to the photosensitive element for an upward emitting structure, in which a semi-transparent anode 74b is used.

This anode 74b can be formed from a very thin metal layer, so that a proportion of the light emitted by the OLED is allowed to pass through the anode towards the photo-sensor. For example, a reflective or black anode with a finite transmission (for example 1 to 10%) is provided, such that enough light can reach the light sensing elements to allow opto-electronic feedback. A metal film of 10 nm to 60 nm (depending on the material) is appropriate, and the transmission can be tuned simply by variation of the thickness of the film. No additional processing steps are required to implement this approach.

If the conductivity of the anode becomes insufficient due to the measures taken to obtain a finite transmission, the anode can be composed of a conductive transparent part on top of the non-transparent layer. The conductive transparent part of the anode can be used to optimise hole injection, independent of the optical properties of the non-transparent part of the anode with finite transmission.

In the arrangement shown in FIG. 7, light (a) enters the photodiode 27 providing the feedback function, but ambient light (c) can still reach the photodiode 27. Measures to avoid this problem are discussed further below. Furthermore, shallow angle light (b) from the LED and the ambient light rays (c) can be piped in the substrate if a glass substrate is used, and carried long distances to cause cross talk between pixels. For this reason, for the implementation of FIG. 7, it may be preferred to use a non-transmissive substrate such as a metal foil.

In order to reduce the passage of light into the substrate, an alternative arrangement shown in FIG. 8 uses a small transparent aperture 150 provided over the diode, in an opaque anode structure 74c. Light is then only transmitted through the anode in the vicinity of the light sensitive device 27.

A top shield 152 is also shown in FIG. 8 for shielding the light sensitive device from ambient light, and if this is a metal, this can also be used to back-up the cathode electrically as shown at 154, because the cathode is made from a relatively low conductivity transparent material, such as ITO. Indeed, some pixel designs already incorporate metallic structures on top of the semitransparent cathode to shunt the cathode, and in this case the top shield 152 can be integrated with these structures with no additional processing steps.

The top shield of FIG. 8 could of course equally be employed in the design of FIG. 7 to reduce the amount of ambient light reaching the light sensitive device 27.

The light sensing element may typically have dimensions of 10×10 μm, in contrast to a pixel size of typically 100×100 μm. As a result, the small transparent gap in the non-transparent anode does not significantly influence the reflective or absorbing function of the anode. The holes 150 can be made in the non-transparent anode with standard lithography processes.

As the non-transparent anode on the active matrix backplane is already patterned, no additional mask steps are required to provide the holes. However, less (or no) light will be generated in the electroluminescent layer above the position of the hole, as there is then no electrode area present. This portion of the EL layer thus is not subjected to the same drive conditions as the remainder of the EL layer and therefore may be illuminated in a less predictable manner and may age differently compared to the remaining EL material. This may reduce the performance of the opto-electronic feedback. However, correct calibration of the feedback operation can take into account the feedback characteristics of the circuit.

The top shield 152 does not need to be significantly greater in size than the hole in the anode. In particular, ambient light that enters the display through the semi-transparent cathode will only propagate in a certain angular range (approximately 0o to 40o) depending on the refractive indices of layers between light sensing element and top of the cathode. The thickness of the stack of layers between the light sensing element 27 and top of the cathode is typically approximately 1 mm, so that the size of the light-shield layer only needs to be equal to the area of the light sensing element (typically 10×10 mm) plus an additional surround of width approximately 1 mm, giving an area of the light-shield of approximately 12×12 mm.

The sensing element generally consists of a photo sensitive region and a non-photo sensitive region, the latter for instance being formed by the contacts. The hole 150 can therefore be limited to the size of the photo sensitive area, while the light sensing element in total can be much larger. By having the light sensor larger than the hole 150, no light passing through the hole 150 is able to enter the substrate and potentially cause cross talk between pixels.

FIG. 9 shows how, for devices manufactured using ink-jet printing, the top shield portions 152 can be integrated with metal bars 79 located above the print dams 78 (as explained with reference to FIG. 6).

As mentioned above, the presence of a hole in the anode will affect the generation of light in the corresponding part of the EL layer. One possible refinement is to fill the hole 150 in the anode 74c with a conductive transparent material. When the conductivity of the conductive transparent material is high enough, light can be generated in the corresponding part of the electroluminescent material layer, so that the generated photocurrent in the light sensing element is representative of the average amount of light generated in the full electroluminescent material layer. The size of the hole 150 in the anode can be chosen such that the generated photocurrent in the light sensing element at a certain light output level of the light-emitting element does not depend critically on the size of the hole or its alignment.

The filling of the hole in the anode also gives a planarized upper surface, which is advantageous for the deposition of subsequent layers. An additional mask step is needed to implement this refinement.

As shown in FIG. 10, the anode can be composed of a conductive transparent layer 75 on top of a non-transparent layer 74c, either conductive or non-conductive. The non-transparent layer 74c contains the hole and is located between the conductive transparent part 75 of the anode and the substrate. The conductive transparent layer 75 ensures that the hole in the non-transparent layer 74c does not influence the generation of light in the electroluminescent material. The hole can be (at least partially) filled with the conductive transparent material 75 of the layer above, as shown schematically in FIG. 10, or not. The additional mask step is again needed to implement this implementation, to pattern the layers 74c and 75.

The conductive transparent layer 75 can either be used as an additional layer between the non-transparent anode 74c and the hole injection layer or can be used as the hole injection layer. In the first case, ITO can for example be used as an additional layer. ITO provides a suitable substrate for the deposition of a hole injection layer.

In the examples above, a light shield 152 is used to block the passage of ambient light to the photodiode through the transparent hole in the anode.

A modification shown in FIG. 11 avoids the need for the light shield.

The photosensitive area of the photosensor 27 is positioned such that the direct incoming ambient light (ray (c)) cannot reach this area. Due to refraction of light, incoming daylight will have angles of around 400 or less to the substrate normal, as mentioned above. Therefore, by positioning the sensor 27 slightly laterally of the hole in the anode, incoming light (c) cannot reach the photodiode 27.

The light produced by the EL layer 76 is emitted in all directions and will be also wave-guided in the plane of the layers. This process enables the photosensor 27 to sense directly emitted light from the EL layer.

This architecture enables the shielding of daylight without any additional processing steps to a conventional top emission display without optical feedback.

The photosensor 27 can be any type of photo-sensitive device, for example a photo diode (N-I-P stack), or a phototransistor. An amorphous silicon PIN/NIP photo-diode may be preferred, as amorphous silicon has high quantum efficiency for photo absorption.

A phototransistor can be formed from amorphous silicon or low temperature polysilicon (LTPS).

If a LTPS phototransistor is employed, the photoactive area is in a narrow region next to the drain. FIG. 12 shows a phototransistor geometry which enables the use of a LTPS phototransistor in the structure of FIG. 11.

The phototransistor 27 is placed such that the photoactive region 270 (close to the drain) is positioned radially outside the hole in the anode. The phototransistor has a circular source and drain pattern, centered with respect to the hole. Again, only light emitted by the emitting layer will be sensed, and ambient light will not reach the drain part of the phototransistor. An advantage is that the total photoactive area can be large compared with the size of the hole in the anode. A display pixel with a large hole in the anode risks being visible by the viewer and therefore the hole should be kept as small as possible.

For completeness, FIG. 13 shows in more detail the layers used to implement the structure of FIG. 8 into the structure of FIG. 6, and FIG. 14 shows in more detail the layers used to implement the structure of FIG. 7 into the structure of FIG. 6.

FIG. 13 shows a PIN/NIP diode stack 27 beneath the hole 150, and with a top contact 28.

FIG. 14 also shows the PIN/NIP diode stack 27 and top contact 28, and shows the anode implemented as a thin metal layer 74d beneath an ITO layer 74e.

The metallic light-shield is particularly desirable when a metallic anode is used in combination with a circular polarizer. In this way, the metallic light-shield does not lower the daylight contrast. An absorbing light shield can be applied irrespective of the chosen anode composite.

From reading the present disclosure, other modifications will be apparent to persons skilled in the art.

1. An active matrix display device comprising an array of display pixels provided over a common substrate (60), each pixel comprising:
a drive transistor circuit provided over the substrate (60); and
an upwardly emitting current-driven light emitting display element (2) provided over the drive transistor circuit, and comprising a lower electrode (74) and an upper substantially transparent electrode (80a); and
a light sensitive device (27) for sensing the display element (2) light output and positioned between the substrate (60) and the display element (2),
wherein a drive transistor (22) of the drive transistor circuit is controlled in response to the light-sensitive device (27) output, and
wherein the lower electrode (74) of the display element is partially transmissive to transmit at most 20% of the light incident on the lower electrode, at least a portion of the transmitted light being directed to the underlying light-sensitive device (27).

2. A device as claimed in claim 1, wherein the lower electrode comprises a metal layer (74c) having a transmission of 1% to 10%.

3. A device as claimed in claim 2, wherein the lower electrode comprises a metal film of 10 nm to 60 nm.

4. A device as claimed in claim 2, wherein the lower electrode comprises a conductive transparent layer (74e) overlying the metal film layer (74c).

5. A device as claimed in claim 1, wherein the lower electrode comprises a substantially opaque layer (74c) provided with an opening (150) in the vicinity of the light sensitive device (27).

6. A device as claimed in claim 5, wherein a substantially transparent conductive material is provided in the opening (150).

7. A device as claimed in claim 6, wherein the substantially transparent conductive material forms a layer (75) overlying the opaque layer (74c).

8. A device as claimed in claim 5, wherein the light sensitive device (27) is positioned beneath and laterally to one side of the opening (150).

9. A device as claimed in claim 5, wherein the light sensitive device (27) is positioned beneath and around the opening (150).

10. A device as claimed in claim 9, wherein the light sensitive device comprises a phototransistor having an inner annular source and an outer annular drain, and wherein the outer annular drain is positioned radially outside the opening (150).

11. A device as claimed in claim 1, wherein the light sensitive device (27) comprises a photodiode.

12. A device as claimed in claim 11, wherein the photodiode (27) comprises a PIN or NIP diode stack or a Schottky diode and top and bottom contact terminals.

13. A device as claimed in claim 1, wherein the device further comprises light blocking or reflecting elements (152) provided on top of the upper electrode and overlying the light sensitive devices (27) of the pixels.

14. A device as claimed in claim 13, wherein the light blocking or reflecting elements (152) are formed from a metal layer which also defines resistance reducing portions (79) for the upper electrode.

15. A device as claimed in claim 1, wherein the substrate (60) comprises a glass substrate.

16. A device as claimed in claim 1, wherein the substrate (60) comprises a metal foil and insulating dielectric layer.
